(19) United States
(12) Patent Application Publication
(10) Pub. No.: US 2014/0021503 A1
(43) Pub. Date: Jan. 23, 2014

(54) SEMICONDUCTOR LIGHT EMITTING DEVICE

(71) Applicant: Panasonic Corporation, Osaka (JP)

(72) Inventors: Shinji YOSHIDA, Shiga (JP); Kazuhiko YAMANAKA, Osaka (JP)

(73) Assignee: Panasonic Corporation, Osaka (JP)

(21) Appl. No.: 14/037,443

(22) Filed: Sep. 26, 2013

Related U.S. Application Data
(63) Continuation of application No. PCT/JP2012/001398, filed on Mar. 1, 2012.

(30) Foreign Application Priority Data
Mar. 31, 2011 (JP) 2011-080740

(51) Int. Cl. H01L 33/50

(52) U.S. Cl. CPC H01L 33/505; B82Y 20/00
USPC 257/98; 977/774

(57) ABSTRACT

A semiconductor light emitting device includes: a package which is made of a resin and includes a recess; a lead frame exposed to a bottom of the recess; a semiconductor light emitting element connected to the lead frame in the recess; a resin layer in contact with the lead frame in the recess and over the bottom of the recess; and a quantum dot phosphor layer above the resin layer and the semiconductor light emitting element, in which the resin layer includes a ceramic fine particle, and the quantum dot phosphor layer includes at least one of semiconductor fine particles having an excitation fluorescence spectrum which differs according to a particle size, and a resin holding the semiconductor fine particles dispersedly.

### CROSS REFERENCE TO RELATED APPLICATIONS

This is a continuation application of PCT International Application No. PCT/JP2012/001398 filed on Mar. 1, 2012, designating the United States of America, which is based on and claims priority of Japanese Patent Application No. 2011-080740 filed on Mar. 31, 2011. The entire disclosures of the above-identified applications, including the specifications, drawings and claims are incorporated herein by reference in their entirety.

### FIELD

The present disclosure relates to semiconductor light emitting devices, and relates in particular to a semiconductor light emitting device using a quantum dot phosphor.

### BACKGROUND

High-intensity white light emitting diodes (LEDs) are used as light sources for lighting and liquid crystal display backlight, for example, and efforts are being made to improve the efficiency and color rendering properties of the light sources. A white LED is made by combining a semiconductor light emitting element which emits blue light with a green phosphor, a yellow phosphor, or a red phosphor. The types of phosphors include an inorganic phosphor, an organic phosphor, and a quantum dot phosphor made of a semiconductor. Patent Literature 1 is an example of the white LED including the inorganic phosphor.

FIG. 9 is a cross sectional diagram which illustrates a conventional semiconductor light emitting device disclosed in i 1.

As shown in FIG. 9, in a conventional semiconductor light emitting device, a semiconductor light emitting element 1 which emits ultraviolet light, blue light, or green light is disposed in a container 8 in which electric terminals 102 and 103 are embedded, and a material 5 containing light emitting particles 6 (inorganic pigment of a light emitting substance) fills the container 8 so as to cover the semiconductor light emitting element 1.

### CITATION LIST

### Patent Literature

[PTL 1] Japanese unexamined patent application publication No. 11-500584

### SUMMARY

### Technical Problem

LED light sources are used as key devices of display devices and lighting equipment because of their small sizes and power consumption, and efforts are being made to improve the efficiency and color rendering properties of high-intensity white LEDs. White LED light sources are generally the combination of blue LED light sources and green phosphors or yellow phosphors. To realize high efficiency and high color rendering properties, phosphors are required which have excellent light emitting properties and energy conversion efficiency. General phosphors for use in white LEDs are crystal fine particles having rare earth ions as an activator, and are often chemically unstable. However, while the light absorption efficiency of these phosphors is in proportion to the concentration of rare earths, extremely high concentration causes concentration quenching which decreases efficiency of light emission. Thus, it has been difficult to realize high quantum efficiency of at least 80%.

In view of the above, many types of semiconductor phosphor fine particles have been proposed which realize the high quantum efficiency by directly using light absorption or light emission at a band edge. In particular, fine particles having a diameter of several nm to several dozen nm, called quantum dot phosphors are expected to be introduced as new phosphor materials which do not include rare earths. Even if fine particles are made of the same material, by controlling a particle size with quantum size effects, a quantum dot phosphor can obtain a fluorescence spectrum of a desired wavelength range in a visible light region. Moreover, a high external quantum efficiency of around 90% is indicated on account of light absorption and fluorescence at a band edge. Therefore, it is possible to provide white LEDs with high efficiency and high color rendering properties.

Furthermore, when a light emitting device such as the white LED is configured using the quantum dot phosphors, the thermal conductivity of a casted epoxy resin layer is low in a structure like the container 108 disclosed in Patent Literature 1. Therefore, in an area away from a package and a frame resin layer which function as heat sinks, heat generation due to Stokes loss caused by the quantum dot phosphors leads to high temperature in the resin layer. As a result, a temperature of the quantum dot phosphors increases to cause deterioration of the quantum dot phosphors, to thereby decrease the efficiency of light emission.

In view of the above, one non-limiting and exemplary embodiment provides a semiconductor light emitting device which can reduce decline in efficiency of light emission by suppressing the increase in the temperature of the quantum dot phosphors.

### Solution to Problem

In view of the above, an aspect of a first semiconductor light emitting device according to the present disclosure feature a semiconductor light emitting device including: a package which is made of a resin and includes a recess; a lead frame exposed to a bottom of the recess; a semiconductor light emitting element connected to the lead frame in the recess; a first resin layer in contact with the lead frame in the recess and over the bottom of the recess; and a second resin layer above the first resin layer and the semiconductor light emitting element, in which the first resin layer includes a ceramic fine particle, and the second resin layer includes at least one of semiconductor fine particles having an excitation fluorescence spectrum which differs according to a particle size, and a resin holding the semiconductor fine particles dispersedly.

With this configuration, a ceramic fine particle is contained in the first resin layer. Accordingly, an effective thermal conductivity of the first resin layer can be increased. Therefore, a radiation property of the second resin layer containing semiconductor fine particles can be increased, so that the increase in the temperature of semiconductor fine particle can be suppressed. Accordingly, the decrease in light emission efficiency, which is caused by deterioration of the semiconductor fine particle due to the increase in temperature, can be suppressed. Consequently, the semiconductor light emitting device with high efficiency and high reliability can be provided.

Furthermore, in one aspect of the first semiconductor light emitting device according to the present disclosure, it is desirable that the second resin layer is enclosed in a transparent substrate, and the transparent substrate and the package surround an area which is filled with the first resin layer.

With this configuration, semiconductor fine particles (quantum dot phosphors) do not come into contact with oxygen so as to be suppressed to deteriorate due to the oxygen. Consequently, the semiconductor light emitting device with high reliability and high color rendering properties can be provided.

Furthermore, in one aspect of the first semiconductor light emitting device according to the present disclosure desirably includes a third resin layer between the first resin layer and the semiconductor light emitting element. Here, the third resin layer does not include the ceramic fine particle.

With this configuration, the semiconductor light emitting element can be thermally shielded by the third resin layer which does not contain ceramic fine particles and has a small thermal conductivity. Therefore, the increase in the temperature of semiconductor fine particles (quantum dot phosphors) can be further suppressed, to thereby provide the semiconductor light emitting device having high luminance and high color rendering properties.

Furthermore, in one aspect of the first semiconductor light emitting device according to the present disclosure, it is desirable that the second resin layer is formed by an electrodeposition method on a surface of a transparent substrate having an electrically conductive area, and is placed above the package to face the semiconductor light emitting element, and the package has an inside which is filled with the first resin layer.

With this configuration, semiconductor fine particles (quantum dot phosphors) can be uniformly dispersed in an oxygen resistant resin. Consequently, the semiconductor light emitting device with high efficiency and high reliability can be provided.

Furthermore, an aspect of a second semiconductor light emitting device according to the present disclosure is a semiconductor light emitting device including a semiconductor light emitting element mounted on a package; a phosphor layer which converts a wavelength; and a transparent resin layer, in which the transparent resin layer is in contact with a heat radiation region in the package and encloses therein the semiconductor light emitting element, the transparent resin layer includes a ceramic fine particle, and the phosphor layer includes at least one of semiconductor fine particles having an excitation fluorescence spectrum which differs according to a particle size, and a resin holding the semiconductor fine particles dispersedly.

With this configuration, ceramic fine particles having an excellent thermal conductivity are dispersed in a resin, so that a transparent resin layer having the excellent thermal conductivity can be formed. Accordingly, even if a high output excitation light source is used, heat can be efficiently radiated from a phosphor layer containing semiconductor fine particles (quantum dot phosphors). Consequently, the semiconductor light emitting device with high luminance and high color rendering properties can be provided.

Furthermore, in one aspect of the second semiconductor light emitting device according to the present disclosure, it is desirable that a second transparent resin layer is placed between the first resin layer which contains the ceramic fine particle and the semiconductor light emitting element. Here, the second transparent resin layer does not include the ceramic fine particle.

With this configuration, the semiconductor light emitting element can be thermally shielded by the second transparent resin layer which does not contain the ceramic fine particles and has the small thermal conductivity. Therefore, the increase in the temperature of the phosphor layer can be suppressed, to thereby provide the semiconductor light emitting device with high luminance and high color rendering properties.

Furthermore, in one aspect of the second semiconductor light emitting device according to the present disclosure, it is desirable that the phosphor layer is enclosed in a transparent substrate, and the transparent substrate and the package surround an area which is filled with the transparent resin layer.

With this configuration, semiconductor fine particles (quantum dot phosphors) do not come into contact with the oxygen, to thereby suppress the deterioration of the semiconductor fine particle due to the oxygen. Consequently, the semiconductor light emitting device with high reliability and high color rendering properties can be provided.

Furthermore, in one aspect of the second semiconductor light emitting device according to the present disclosure, it is desirable that the phosphor resin layer is formed by an electrodeposition method on a surface of a transparent substrate having an electrically conductive area, and is placed above the package to face the semiconductor light emitting element, and the package has an inside which is filled with the transparent resin layer containing the ceramic fine particle.

With this configuration, semiconductor fine particles (quantum dot phosphors) can be uniformly dispersed in the oxygen resistant resin, to thereby provide the semiconductor light emitting device with high reliability and high color rendering properties.

Furthermore, an aspect of a third semiconductor light emitting device according to the present disclosure includes a package having a recess; a semiconductor light emitting element mounted in the package; and a resin layer which is formed inside the package, and holds, in a dispersed state, a phosphor which converts a wavelength and a ceramic fine particle, in which the phosphor includes an aggregation containing at least one quantum dot phosphor, the aggregation is coated with a transparent acrylic resin film or a silicon oxide, and the semiconductor light emitting element is coated with the resin layer.

With this configuration, semiconductor fine particles (quantum dot phosphors) are dispersed and contained in the resin layer which contains ceramic fine particles and has an excellent thermal conductivity, to thereby efficiently dissipate heat generated by self-heating of the semiconductor fine particles. Furthermore, a surface of the quantum dot phosphor is coated with an acrylic resin film or a silicon oxide, to thereby suppress the deterioration in quantum dot phosphors due to photo-oxidation. As described above, in the present embodiment, both the increase in the temperature of quantum dot phosphors and the photo-oxidation of the quantum dot phosphors can be suppressed, to thereby provide the semiconductor light emitting device with high efficiency, high luminance, and high color rendering properties.

Furthermore, in one aspect of the first to third semiconductor light emitting devices according to the present disclosure, the ceramic fine particle is a white fine particle which reflects a visible light ray.

With this configuration, the light emitted from the semiconductor light emitting element is uniformly emitted to the phosphor layer (or the resin layer containing phosphors and semiconductor fine particles), to thereby provide the semiconductor light emitting device which does not emit uneven light.

Furthermore, in one aspect of the first to third semiconductor light emitting devices according to the present disclosure, the ceramic fine particle may be a transparent fine particle which allows a visible light ray to pass through.

With this configuration, the light from the semiconductor light emitting element is emitted to the phosphor layer (or the resin layer containing phosphors or semiconductor fine particles) without any loss, to thereby provide the semiconductor light emitting device with high efficiency.

Furthermore, in one aspect of the first to third semiconductor light emitting devices according to the present disclosure, the ceramic fine particle may be a diamond fine particle.

With this configuration, the increase in the temperature of the phosphor layer (or the resin layer containing phosphors or semiconductor fine particles) can be suppressed by diamond fine particles having a high thermal conductivity, to thereby provide the semiconductor light emitting device with high reliability and high color rendering properties.

Furthermore, in one aspect of the first to third semiconductor light emitting devices according to the present disclosure, the ceramic fine particle may absorb light emitted from the semiconductor light emitting element, and emit excited light of the semiconductor fine particle as fluorescence.

With this configuration, the light from the semiconductor light emitting device undergoes the wavelength conversion using ceramic fine particles, to thereby provide the semiconductor light emitting device with high color rendering properties. Furthermore, the wavelength conversion is performed on the light from the semiconductor light emitting element using ceramic fine particles to causes the Stoke loss in semiconductor fine particles (phosphors) to decrease, to thereby enable self-heating of the semiconductor light emitting element to be suppressed. Therefore, the semiconductor light emitting device with high reliability can be provided.

Furthermore, in one aspect of the first to third semiconductor light emitting devices according to the present disclosure, the ceramic fine particle has the particle size in a range from 100 nm to 700 nm inclusive.

With this configuration, the visible light ray can be efficiently scattered and emitted to the phosphor, to thereby provide the semiconductor light emitting device with high efficiency and high color rendering properties.

### Advantageous Effects

According to the present disclosure, a resin layer contains a ceramic fine particle, so that a thermal conductivity in the resin layer can be increased. Therefore, increase in a temperature of a phosphor or a semiconductor fine particle due to self-heating thereof can be suppressed. Accordingly, the semiconductor light emitting device with high reliability and high efficiency can be provided.

### BRIEF DESCRIPTION OF DRAWINGS

These and other objects, advantages and features will become apparent from the following description thereof taken in conjunction with the accompanying drawings that illustrate a specific embodiment of the present invention.

FIG. 1 is a cross-sectional schematic diagram which shows a semiconductor light emitting device according to Embodiment 1.

FIG. 2 is a cross-sectional diagram which shows assembling processes for the semiconductor light emitting device according to Embodiment 1.

FIG. 3 is a cross-sectional schematic diagram which shows a semiconductor light emitting device according to Embodiment 2.

FIG. 4 is a conceptual diagram for illustrating electrodeposition processes in the semiconductor light emitting device according to Embodiment 2.

FIG. 5 is a cross-sectional schematic diagram which shows a semiconductor light emitting device according to Embodiment 3.

FIG. 6 is a cross-sectional schematic diagram which shows a semiconductor light emitting device according to Embodiment 4.

FIG. 7 is a cross-sectional diagram which shows assembling processes for the semiconductor light emitting device according to Embodiment 4.

FIG. 8 is a cross-sectional schematic diagram which shows a semiconductor light emitting device according to Embodiment 5.

FIG. 9 is a cross-sectional view according to a conventional semiconductor light emitting device.

### DESCRIPTION OF EMBODIMENTS

Among the structural elements in the following description, the structural elements not recited in Claims are not necessarily required to achieve the problem of the present disclosure, but are used to form a preferable embodiment. It should be noted that in the drawings, the same reference numerals are given to the same structural elements, and the detailed explanation will be omitted or simplified.

### Embodiment 1

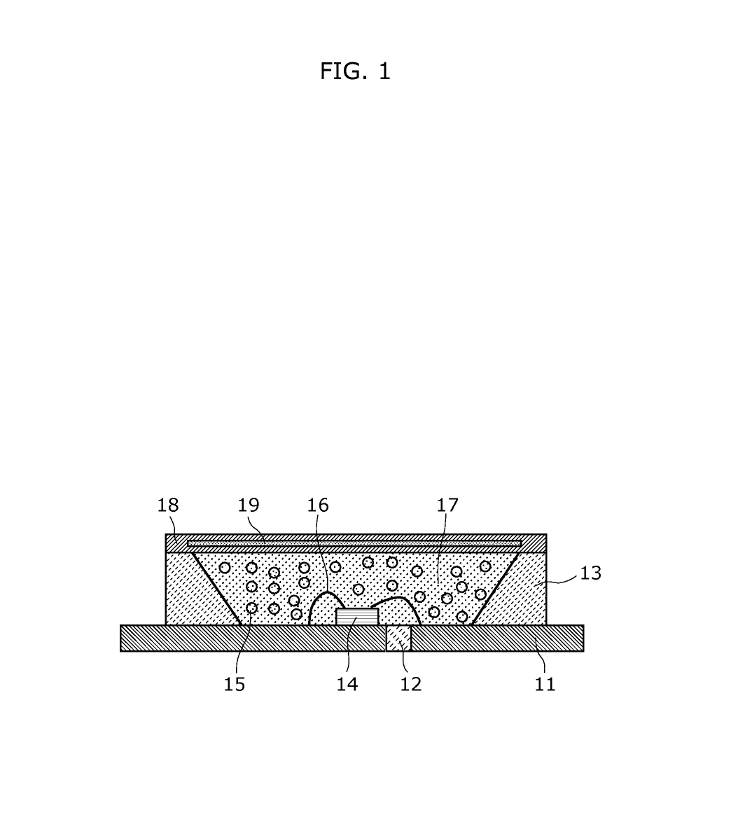

First, a semiconductor light emitting device according to Embodiment 1 is described with reference to FIG. 1.

FIG. 1 is a cross-sectional schematic diagram which shows the semiconductor light emitting device according to Embodiment 1. In the present embodiment, a lead frame package is used as a package. The semiconductor light emitting device according to the present embodiment is a white LED light source which emits white light.

As shown in FIG. 1, the semiconductor light emitting device according to Embodiment 1 includes a package which is made of a resin and has a recess, a lead frame 11, an insulating resin layer 12, and a light reflection resin layer 13. The lead frame 11 is exposed to a bottom of the recess of the package, and a light emitting diode (LED) is mounted, as a semiconductor light emitting element 14, on the lead frame 11 in a range in which the lead frame 11 is exposed to the bottom of the recess. A P-type electrode and N-type electrode of the semiconductor light emitting element 14 serving as the LED have electric contacts with the lead frame 11 via gold wires 16.

A resin layer 17 (first resin layer) made of a transparent resin fills the package so as to enclose the semiconductor light emitting element 14. According to the present embodiment, an area surrounded by a glass plate 18 which is a transparent substrate and the package is filled with the resin layer 17. The resin layer 17 comes into contact with the lead frame 11 within the recess of the package, and covers the bottom of the recess. In the resin layer 17, ceramic fine particles 15 are dispersed.

A quantum dot phosphor layer 19 (second resin layer) is a phosphor layer formed above the resin layer 17 and the semiconductor light emitting element 14. In the present embodiment, the quantum dot phosphor layer 19 is sealed by the glass plate 18 and disposed in contact with the resin layer 17 which fills the package. The quantum dot phosphor layer 19 includes at least one semiconductor fine particle (quantum dot phosphor) having excitation fluorescent spectrums which differs according to particle diameter and a resin which holds semiconductor fine particles dispersedly.

As described above, the present embodiment uses the quantum dot phosphor layer 19 serving as a phosphor layer which is enclosed in the glass plate 18. To be specific, the quantum dot phosphor layer 19 obtained by dispersing quantum dot phosphors in an acrylic resin is enclosed in the glass plate 18. An outer periphery of the glass plate 18 is sealed by an epoxy resin so that the acrylic resin is not directly contact with air.

As a resin material for the resin layer 17 in the present embodiment, a silicone resin is used. Since a thermal conductivity of the silicone resin is around 0.3 W/mK which is a small value, heat of the quantum dot phosphor layer 19 cannot be sufficiently radiated at this thermal conductivity level. This causes a temperature of the quantum dot phosphor to increase due to self-heating by Stokes loss, thereby decreasing the light emission efficiency. In view of the above, in the present embodiment, a ceramic fine particle 15 having an excellent thermal conductivity is contained in the silicone resin, to increase an effective thermal conductivity of the resin layer 17. Accordingly, increase in the temperature of the quantum dot phosphor layer 19 is suppressed.

As described above, with the semiconductor light emitting device according to the present embodiment, the resin layer 17 (first resin layer) contains ceramic fine particles, so that the effective thermal conductivity of the resin layer 17 can be increased. With this, heat radiation properties of the quantum dot phosphor layer 19 (second resin layer) can be increased, to thereby suppress the increase in the temperature of the quantum dot phosphor layer 19. Accordingly, it can be suppressed that the quantum dot phosphors (semiconductor fine particles) in the quantum dot phosphor layer 19 deteriorates due to the temperature increase, which causes light emission efficiency to decrease. Consequently, the semiconductor light emitting device with high efficiency and high reliability can be provided.

In the present embodiment, the quantum dot phosphor layer 19 is enclosed in the glass plate 18. With this configuration, the quantum dot phosphor in the quantum dot phosphor layer 19 is not in contact with oxygen, to thereby suppress deterioration of the quantum dot phosphor due to the oxygen. Consequently, the semiconductor light emitting device with high reliability and high color rendering properties can be provided.

It should be noted that in the present embodiment, an aluminum nitride (AlN) was used as the ceramic fine particle 15. The AlN has the thermal conductivity of about 200 W/mK, which is about triple-digit larger than that of the silicone resin. In addition, the AlN has a band gap of more than or equal to 6 eV, so that the AlN is transparent to a light ray in a visible light ray area. Accordingly, for the ceramic fine particle 15, an AlN fine particle may be used, for example. When the AlN is used as the ceramic fine particle 15, the AlN may be, for example, broken up to be fine particles so as to be mixed in the silicone resin, followed by being injected in the package to fill thereof. Then, the obtained result may be heated up at 150 degree Celsius to be cured. In the present embodiment, the AlN fine particle was contained in the silicone resin at 10 vol % in a volume ratio. In this case, the effective thermal conductivity of the silicone resin became 14.3 W/mK.

Although the AlN fine particles are used as the ceramic fine particles 15 in the present embodiment, a material which does not absorb light emitted from the semiconductor light emitting element 14 may be used as a material to be dispersed in the resin layer 17. For example, SiO₂, SiN, GaN, Al₂O₃, TiO₂, ZrO₂, or ZnO₂ may be used as the material. Since each of the AlN and the GaN has a high thermal conductivity, the effective thermal conductivity of the silicone resin can be increased even when the AlN or the GaN is dispersed at a low concentration.

In addition, in the present embodiment, the glass plate 18 including the quantum dot phosphor layer 19 is set up on the resin layer 17. At this time, it is desirable that the resin layer 17 and the glass plate 18 are stuck to each other, in order to increase a cross-sectional area from which the heat is radiated.

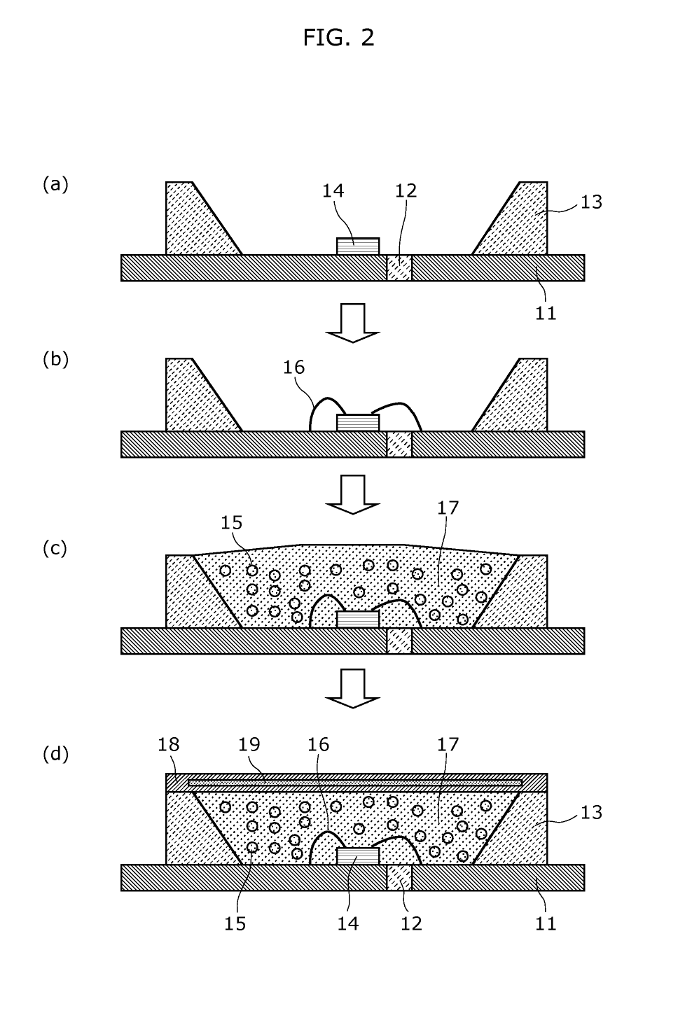

Next, a method for manufacturing a semiconductor light emitting device (an assembling method) according to Embodiment 1 is described with reference to FIG. 2. FIG. 2 is a diagram which shows assembling processes for the semiconductor light emitting device according to Embodiment 1.

First, as shown in (a) of FIG. 2, the LED which serves as the semiconductor light emitting element 14 is mounted on a lead frame package including the lead frame 11.

Subsequently, as shown in (b) of FIG. 2, a wire bonding process is performed to connect the gold wires 16 to the semiconductor light emitting element 14.

Then, as shown in (c) of FIG. 2, the silicone resin containing the ceramic fine particles 15 is injected in the recess to form the resin layer 17. At this time, the silicone resin is injected so as to bit bulge from the recess of the recess-shaped package.

Next, degassing processing (not shown) is performed to remove gas remaining in the silicone resin. In the present embodiment, the LED in which the silicone resin was injected was set in a vacuum chamber connected to an oil-sealed rotary pump, and then to be left for 30 minutes.

Next, as shown in (d) of FIG. 2, the glass plate 18 and the resin layer (silicone resin) 17 are stuck to each other so that the resin layer which bulges is pressed down by the glass plate 18 which holds therein the quantum dot phosphor layer 19. With this, the resin layer 17 is pressed down by the glass plate 18 to extend horizontally, and also comes into contact with the glass plate 18 uniformly.

Lastly, the silicone resin is thermally cured by heating (not shown), to thereby manufacture the semiconductor light emitting device which is shown in FIG. 1.

### Embodiment 2

Next, a semiconductor light emitting device according to Embodiment 2 is described.

In Embodiment 1, the quantum dot phosphor layer which is enclosed in the glass plate is used as the phosphor layer. However, the structure using the two glass plates to sandwich the quantum dot phosphor layer causes the quantum dot phosphor layer to be thermally shielded by the glass plates, thereby resulting in insufficient heat radiation by the resin layer containing the ceramic fine particles.

In addition, with the structure that the quantum dot phosphor layer is enclosed in the glass plate, another problem is raised. For example, it is difficult to sufficiently secure a sealing performance by the glass, or to disperse the quantum dot phosphors in the quantum dot phosphor layer uniformly.

In view of the above, it is desirable that quantum dot phosphors are uniformly dispersed in a layer, and a quantum dot phosphor layer and a resin layer containing ceramic fine particles come into contact with each other.

FIG. 3 is a cross-sectional schematic diagram which shows the semiconductor light emitting device according to Embodiment 2.

As shown in FIG. 3, in the semiconductor light emitting device according to Embodiment 2, a quantum dot phosphor resin layer 22 (second resin layer) is formed by an electrodeposition method on a surface of a transparent substrate which has an electrically conductive area, and is placed above the package to face a semiconductor light emitting element 14. The package has an inside which is filled with a resin layer 17 (first resin layer), and the resin layer 17 is sealed by a sealing member including the quantum dot phosphor resin layer 22.

In the present embodiment, as the sealing member for sealing the resin layer 17, an indium tin oxide (ITO) thin film is formed on a surface of a transparent glass plate 20 (transparent substrate) as a transparent electrode film 21 (electrically conductive area), and the quantum dot phosphor resin layer 22 (second resin layer) is deposited on the ITO thin film using the electrodeposition method. The ITO thin film can be created using a spattering method. The sealing member configured as above is placed in such a manner that the quantum dot phosphor resin layer 22 comes into contact with the resin layer 17 containing ceramic fine particles 15.

Here, a method for manufacturing the quantum dot phosphor resin layer 22 which functions as the phosphor layer is described. The quantum dot phosphors are emulsified with a water-soluble resin solvent or a water-dispersible resin solvent so as to be uniformly dispersed. In the present embodiment, the epoxy resin is used as the electrodeposited resin. The epoxy resin has an oxygen permeability around double-digit to triple-digit lower than that of a silicone resin, and is one of the resins which can be easily soluble or dispersible in water by amination. In addition to the epoxy resin, a fluorine resin also has a high oxygen barrier property and high moisture resistance, so that a photo-oxidation reaction can be suppressed by dispersing the quantum dot phosphors in the resin. The water-soluble resin has a resin molecular framework a part of which is ionized in aqueous solution or has an electrical polarity. The polar part and an ionized area of a resin molecule are stabilized by hydration. Therefore, the water-soluble resin is dissolved or dispersed in water, and can be emulsified. At this time, if a particle size of the phosphor fine particle is large, the phosphor fine particle is not sufficiently captured by the resin solvent molecule, causing deposition and settlement. On the other hand, the particle size of the quantum dot phosphor is around 1 nm to 20 nm, which is equivalent to or less than the size of a water-soluble resin molecule. Therefore, it is possible to disperse quantum dot phosphors in a resin solution uniformly and at high concentration.

The semiconductor fine particles used in the present disclosure are quantum dot phosphors having an indium phosphorous (InP) as a nucleus and a diameter of around 1 nm to 10 nm. The material of the phosphors is required to be a water-insoluble material, so that a cadmium quantum dot phosphor or a chalcogenide fine particle may be used, in addition to InP.

Many of the quantum dot phosphors have a two-layer structure or a three-layer structure called a core-shell structure for improving efficiency of light emission and reliability. Here, in order to efficiently perform dispersion in a water-soluble resin solvent, the chemical property of the outermost layer of the quantum dot phosphor is important. The emulsification of the quantum dot phosphor results from interaction with an alkyl backbone, so that the outermost layer of the phosphor fine particle needs to be formed of a non-polar or weak polar ligand or layer. With this structure, the quantum dot phosphors are captured by a resin backbone on account of hydrophobic interaction.

It should be noted that the quantum dot phosphor used in the present embodiment has the three-layer structure in which the InP is the core and an outside thereof is the shell layer made of ZnS. As the outermost layer, octane hydrocarbon is bound to an outer surface of the shell layer as a ligand, resulting in a ligand layer. The ligand layer made of the hydrocarbon having a strong hydrophobic property is arranged on the outermost layer, to thereby allow the quantum dot phosphors to be efficiently captured by the backbone of a resin molecule in the aqueous solution. Consequently, quantum dot phosphors can be emulsified at high concentration and uniformity. A smaller molecular weight is preferable in order to improve dispersibility into the resin solution. To be specific, since the ligand layer needs to be present in a liquid state at a room temperature, the number of carbons should be preferably 15 or less.

In the present embodiment, the quantum dot phosphor resin layer 22 is formed using a cationic electrodeposition method. FIG. 4 is a schematic drawing which shows electrodeposition processes in the method.

As shown in FIG. 4, a cathode electrode 26 and an anode electrode 25 which is a counter electrode to the cathode electrode 26 are soaked in an epoxy resin solution 23 containing dispersed quantum dot phosphors 24. The epoxy resin is aminated (positively ionized), and the cathode electrode 26 is coated with a coating member so as to form an electro-deposited film 27 on the coating member. In contrast, if the resin solvent is of an acid system, an anionic electrodeposition method is achieved by using the coating member as an anode electrode. The electro-deposited film 27 (resin coating film) obtained by these methods undergoes a drying process and a curing process to be finally shaped, resulting in the quantum dot phosphor resin layer 22. In the electrodeposition method, the resin layer is formed only in an energized area, so that patterning of forming the resin by the electrodeposition can be achieved by protecting a desired position on the ITO film with an insulating resist. It should be noted that in the present embodiment, the electrodeposition was performed in such a manner that an area where a periphery of a package and a glass plate are contact with each other is protected with the resist so that an electrodeposited layer is not formed on the area. Although the epoxy resin is used as the resin solution 23 in the present embodiment, a fluorine resin may be used. Since such resin is excellent in oxygen resistance and moisture resistance, deterioration of the quantum dot phosphor can be efficiently suppressed. The manufactured quantum dot phosphor resin layer 22 is set to be in contact with the resin layer 17 which contains the ceramic fine particles 15, and is thermally cured in the same manner as in Embodiment 1.

As described above, with the semiconductor light emitting device according to the present embodiment, the ceramic fine particles are contained in the resin layer 17 (first resin layer), to thereby increase an effective thermal conductivity thereof, like in Embodiment 1. With this, heat radiation properties of the quantum dot phosphor layer 22 (second resin layer) can be increased, to thereby suppress increase in a temperature of the quantum dot phosphor layer 22. Accordingly, it can be suppressed that the quantum dot phosphors (semiconductor fine particles) in the quantum dot phosphor layer 22 deteriorates due to the temperature increase, leading to decrease in the light emission efficiency.

In addition, in the present embodiment, the quantum dot phosphor resin layer 22 is arranged to be in contact with the resin layer 17, so that a heat radiation property of the quantum dot phosphor resin layer 22 can be further increased in comparison with Embodiment 1.

In the present embodiment, the quantum dot phosphor resin layer 22 is formed on the surface of the transparent substrate having the electrically conductive area resulted from the electrodeposition method, so that the quantum dot phosphors can be uniformly dispersed in an oxygen resistant resin. Consequently, the semiconductor light emitting device with high reliability and high color rendering properties can be provided.

### Embodiment 3

Next, a semiconductor light emitting device according to Embodiment 3 is described.

Although in Embodiment 1 and 2, the phosphor layer (quantum dot phosphor layer 19 or the quantum dot phosphor resin layer 22) which is in contact with the resin layer 17 containing the ceramic fine particles 15 includes a glass substrate, the grass substrate is not necessarily needed.

Accordingly, in Embodiment 3, a resin film containing quantum dot phosphors is used, as a phosphor layer, instead of a glass substrate.

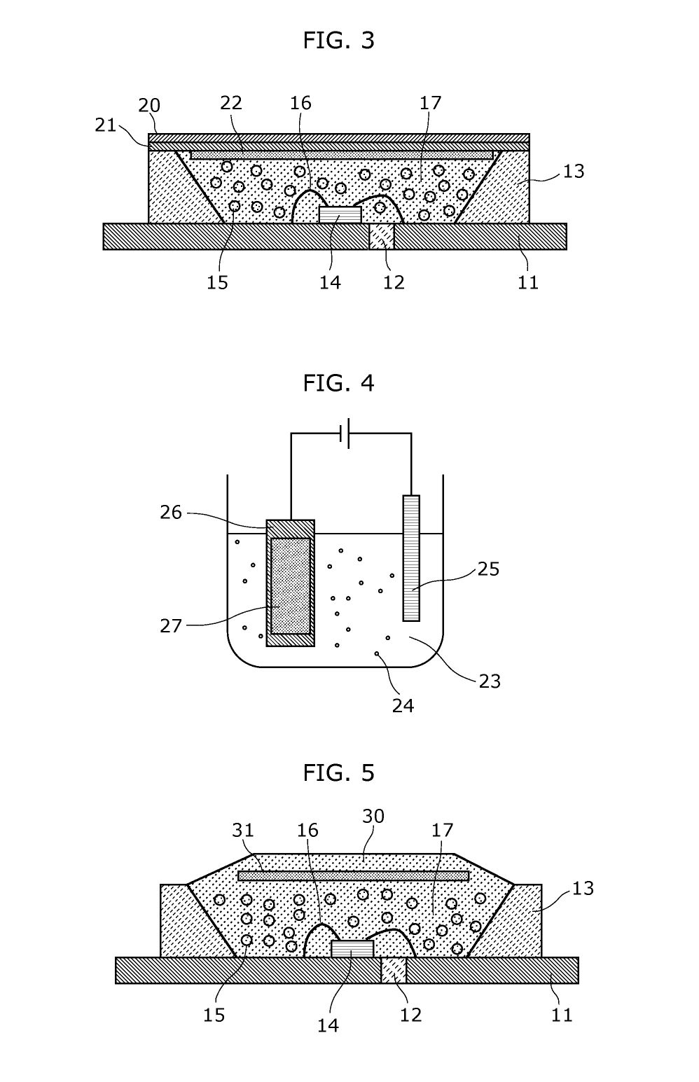

FIG. 5 is a cross-sectional schematic diagram which shows the semiconductor light emitting device according to Embodiment 3.

As shown in FIG. 5, in the semiconductor light emitting device according to the present embodiment, a quantum dot phosphor film 31 (second resin layer) is provided in a transparent resin layer 30 which is made of a silicone resin and is formed above a resin layer 17 (first resin layer). The quantum dot phosphor film 31 is manufactured in such a manner that a resin layer containing the quantum dot phosphors is formed on a flexible transparent conductive substrate, using an electrodeposition method.

The quantum dot phosphor film 31 may be assembled in such a manner that the quantum dot phosphor film 31 is mounted on the resin layer 17 made of a silicone resin, and thermal curing is performed on the silicone resin. Here, it is more desirable that the quantum dot phosphor film 31 is embedded inside the resin layer in order to further enhance adhesion of the quantum dot phosphor film 31 and the silicone resin.

In view of the above, in the present embodiment, the quantum dot phosphor film 31 is set on the resin layer 17, and then a resin layer 30 made of the silicone resin is again injected from above the quantum dot phosphor film 31, and thermally curing is performed thereon. With this configuration, the quantum dot phosphor film (resin film) does not peel off, to thereby provide the semiconductor light emitting device with high reliability.

As described above, with the semiconductor light emitting device according to the present embodiment, the resin layer 17 (first resin layer) contains ceramic fine particles, to thereby increase an effective thermal conductivity of the resin layer 17. With this, heat radiation properties of the quantum dot phosphor film 31 (second resin layer) can be increased, to thereby suppress increase in the temperature of the quantum dot phosphor layer 31. Accordingly, it can be suppressed that the quantum dot phosphors (semiconductor fine particles) in the quantum dot phosphor film 31 deteriorates due to the temperature increase, causing a light emission efficiency to decrease.

### Embodiment 4

Next, a semiconductor light emitting device according to Embodiment 4 is described.

Since a thermal conductivity of a resin containing ceramic fine particles increases, heat generated due to Stokes loss in a phosphor layer can be radiated, while a phosphor layer is susceptible to effect of heat generated by operation of an LED. In particular, when the LED is caused to operate at high output, a junction temperature in the LED may be over 100 degree Celsius. This may accelerate deterioration of the phosphor.

In view of the above, in Embodiment 4, the LED is enclosed in a resin layer which does not contain the ceramic fine particles to radiate heat generated in the phosphor layer to the electrically conductive area of a lead frame, and simultaneously not to conduct heat of the LED to the phosphor layer.

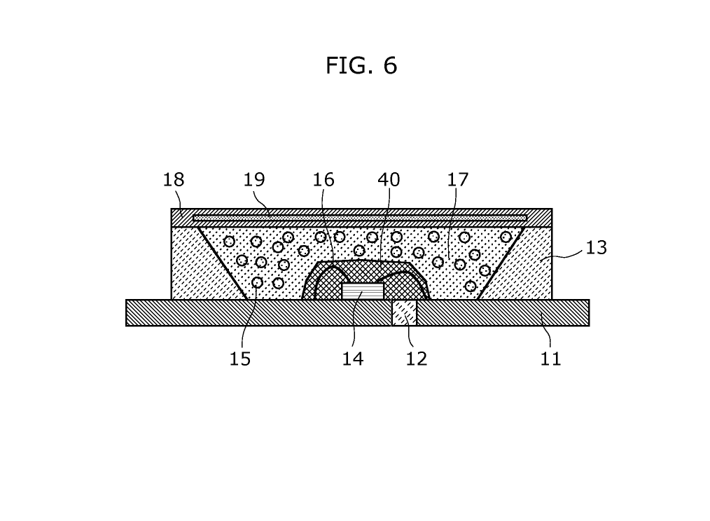

FIG. 6 is a cross-sectional schematic diagram which shows the semiconductor light emitting device according to Embodiment 4.

As shown in FIG. 6, in the semiconductor light emitting device according to the present embodiment, a resin layer 40 (third resin layer) is further formed between a resin layer 17 (first resin layer) and a semiconductor light emitting device 14 in the semiconductor light emitting device according to Embodiment 1. The resin layer 40 does not include the ceramic fine particles, and is a transparent resin layer formed only by a transparent resin made of a silicone resin and the like. In the present embodiment, the semiconductor light emitting device 14 is enclosed in the resin layer 40.

The resin layer 40 does not include the ceramic fine particles, and has a thermal conductivity lower than that of the resin layer 17. Accordingly, the heat from the semiconductor light emitting device 14 is blocked by the resin layer 40, so that the heat from the semiconductor light emitting device 14 can be suppressed to be conducted to a quantum dot phosphor layer 19, even when the semiconductor light emitting element 14 is operated at high output. With this, the increase in the temperature of the quantum dot phosphor layer 19 can be efficiently suppressed by the resin layer 17.

As described above, with the semiconductor light emitting device according to the present embodiment, heat radiation properties of the quantum dot phosphor layer 19 (second resin layer) can be increased by the resin layer 17 (first resin layer) containing the ceramic fine particles, and the heat of the semiconductor light emitting element 14 can be blocked by the resin layer 40 (third resin layer) which does not contain the ceramic fine particles. With this, the increase in the temperature of the quantum dot phosphor layer 19 can be further suppressed, to thereby further suppress light emission efficiency from decreasing due to deterioration of the quantum dot phosphors (semiconductor fine particles) in the quantum dot phosphor layer 19, caused by the increase in the temperature. Accordingly, the semiconductor light emitting device with high efficiency, high luminance, high reliability, and high color rendering properties can be provided.

In the present embodiment, it is desirable that the resin layer 17 containing ceramic fine particles 15 is in contact with the electrically conductive area of the lead frame in order to secure a route for radiating the heat generated due to Stokes loss in the quantum dot phosphor layer 19. With this configuration, both heat radiation of the quantum dot phosphor layer 19 and heat shielding for the semiconductor light emitting device can be further enhanced, so that the increase in the temperature of the quantum dot phosphor layer 19 can be efficiently suppressed even during a high output operation of the semiconductor light emitting element 14, to thereby provide the semiconductor light emitting device with higher reliability.

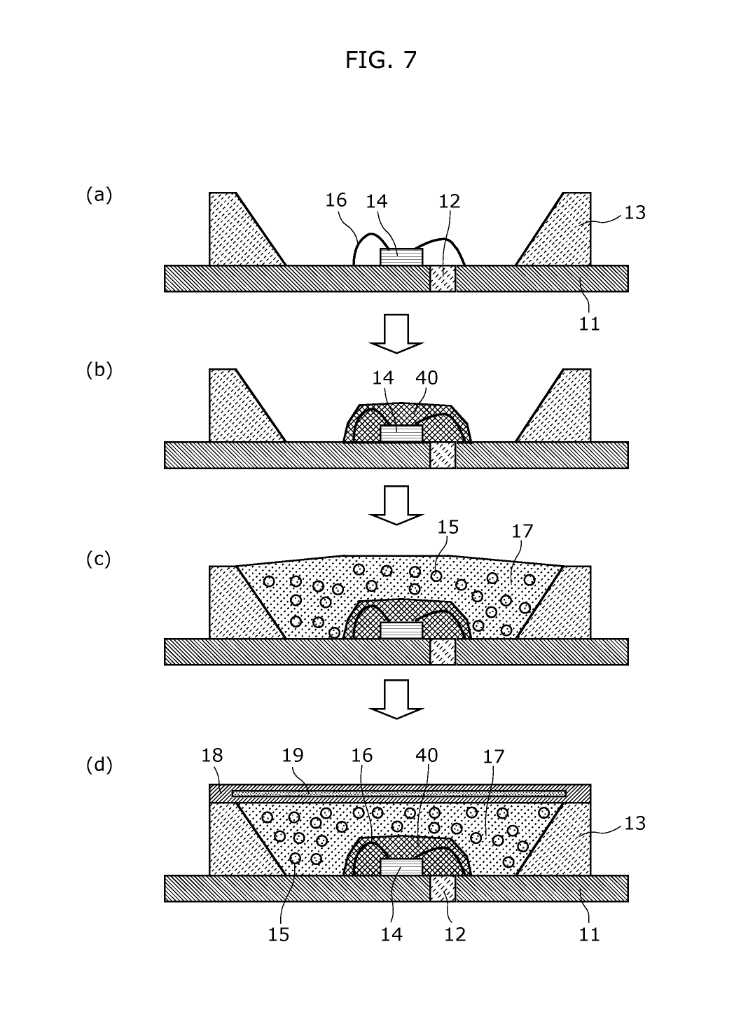

Next, a method (assembling method) of manufacturing the semiconductor light emitting device according to the present embodiment is described with reference to FIG. 7. FIG. 7 is a diagram which shows an assembling process of the semiconductor light emitting device according to Embodiment 4.

First, under the condition that the semiconductor light emitting element 14 (LED) is mounted on and connected to a lead frame 11 with wire bonding (see (a) of FIG. 7), the transparent resin layer 40 made of the silicone resin is partly injected so that only the semiconductor light emitting element 14 is enclosed (see (b) of FIG. 7).

Next, degassing is performed on the silicone resin in the condition shown in the (b) of FIG. 7. For example, the silicone resin (resin layer 40) is shaped by conducting a thermal curing processing at 150 degree Celsius for 30 minutes.

Next, the resin layer 17 made of the silicone resin containing the ceramic fine particles 15 is injected (see (c) of FIG. 7), followed by performing the degassing processing like Embodiment 1. Then, a glass plate 18 in which the quantum dot phosphor layer 19 is enclosed is pressed from above, and the resin layer 17 is thermally cured.

### Embodiment 5

Next, a semiconductor light emitting device according to Embodiment 5 is described.

Quantum dot phosphors may be mixed in a silicone resin which contains ceramic fine particles and has a high thermal conductivity. With this, heat of the quantum dot phosphors due to Stokes loss is radiated to adjacent ceramic fine particles, so that increase in a temperature of the quantum dot phosphors can be suppressed.

However, since the silicone resin has high oxygen permeability, deterioration of the quantum dot phosphors due to photo-oxidation is concerned. Since a quantum dot phosphor has a small particle diameter, the ratio of atoms on the surface of the fine particles is high. Thus, the quantum dot phosphors are often chemical unstable. In particular, for excited fluorescence under a high-temperature environment, a major problem is that photo-oxidation reaction proceeds on a surface of the quantum dot phosphor, which may lead to precipitous decrease in efficiency of light emission.

In view of the above, in Embodiment 5, a surface of an aggregation including a single or a plurality of quantum dot phosphors is coated with a transparent resin or an inorganic coating film which have oxygen barrier properties and moisture resistance properties to configure a quantum dot fine particle aggregation. Then, the quantum dot fine particle aggregation and ceramic fine particles are mixed in the silicone resin. With this, a high heat-radiation LED having high reliability can be provided.

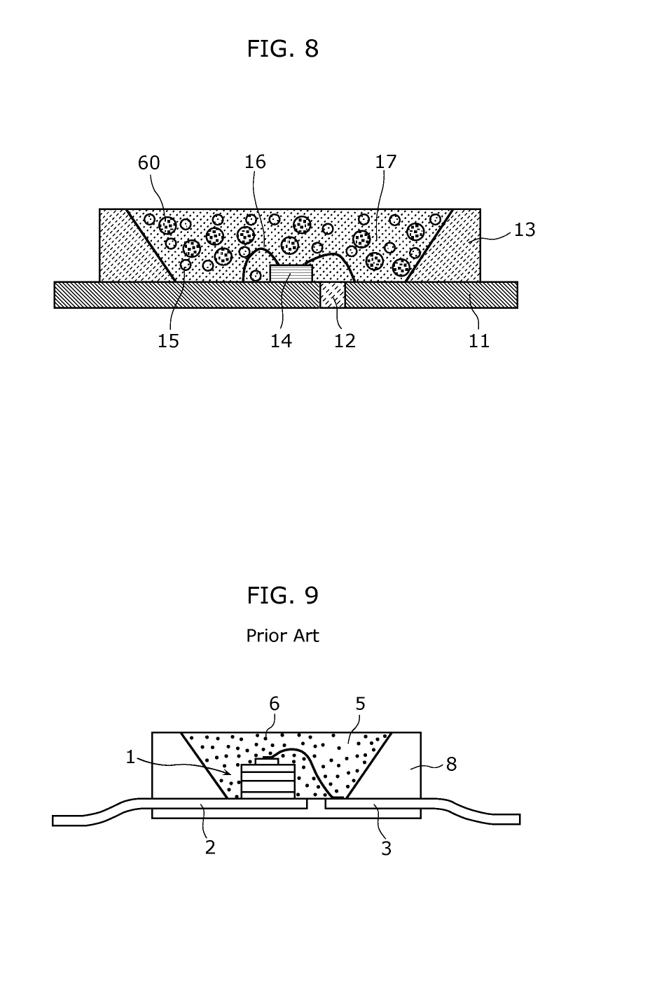

FIG. 8 is a cross-sectional schematic diagram which shows the semiconductor light emitting device according to Embodiment 5.

As shown in FIG. 8, a semiconductor light emitting device according to the present embodiment includes a package which is made of a resin and has a recess, a semiconductor light emitting element 14 mounted inside the package, and a resin layer 17 formed inside the package. In the resin layer 17, a quantum dot fine particle aggregation 60 which is a phosphor converting a wavelength and ceramic fine particles 15 are dispersed in and held by the transparent resin such as a silicone resin.

The quantum dot fine particle aggregation 60 includes an aggregation which contains a single or a plurality of quantum dot phosphors, as described above. The aggregation has a surface coated with a material having oxygen barrier properties and moisture resistance properties. In the present embodiment, the aggregation is coated with a transparent acrylic resin film. The semiconductor light emitting element 14 is tightly coated with the resin layer 17.

Although in the present embodiment, the acrylic resin film is used as a coating film for the quantum dot fine particle aggregation 60, a transparent inorganic coating film, such as a transparent silicon oxide (SiO₂), may be used.

As described above, with the semiconductor light emitting device according to the present embodiment, heat radiation properties of the quantum dot phosphor layer 19 (second resin layer) can be increased using the resin layer 17 (first resin layer) containing the ceramic fine particles 15, and deterioration of the quantum dot phosphors due to photo-oxidation can be suppressed by the acrylic resin film and the like which coats the surface of the quantum dot phosphor. As described above, in the present embodiment, both the increase in the temperature of the quantum dot phosphor and the photo-oxidation of the quantum dot phosphor can be suppressed, to thereby provide the semiconductor light emitting device with high efficiency, high luminance, and high color rendering properties.

### Embodiment 6

Next, a semiconductor light emitting device according to Embodiment 6 is described.

Light emitted form an LED has a tendency that luminance is highest at immediately above the LED and decreases around the LED. Accordingly, the light is not uniformly emitted to a phosphor layer, causing unevenness in light emission.

In view of the above, in Embodiment 6, a white fine particle which reflects a visible light ray is used as a ceramic fine particle 15 in the semiconductor light emitting device according to each of Embodiments 1 to 5. This allows light from the LED to be scattered by white fine particles, to thereby achieve an even light emission on the phosphor layer. As the white fine particle, a titanium oxide (TiO₂) can be used, for example.

It is indispensable that the ceramic fine particles 15 do not absorb an emission wavelength of the LED and a fluorescence wavelength of a quantum dot phosphor. However, the ceramic fine particles 15 sometimes reflect the light from the LED intensively depending on a particle size. In order to efficiently reflect the light from the LED, particle diameter of a fine particle for scattering the light desirably is as large as a wavelength of the light. The material forming the ceramic fine particle 15 is transparent with respect to light emitted by the LED. However, when the size of the fine particle is around the wavelength of the LED, a scattering phenomenon of light called Mie scattering occurs. Therefore, even when fine particles are made of a transparent material, white scattering occurs.

However, the fine particle becomes further smaller, causing the scattering phenomenon to be occupied by light scattering called Rayleigh scattering. Scattering intensity is proportional to the 6th power of the particle diameter. Therefore, if the fine particle is too small, the fine particles are transparent again with respect to the light emitted by the LED. In order to efficiently scatter light, the size of the fine particle needs to be around one quarter wavelength to one wavelength of the light emitted by the LED. Since a visible light region of the white LED is in the range from 400 nm to 700 nm, it is desirable that the particle diameter of the ceramic fine particle 15 is in a range from the 100 nm to 700 nm. In particular, to intensively reflect light (450 nm) of a blue LED, the particle diameter in the range from 100 nm to 450 nm is desirable.

Although in the present embodiment, TiO₂ is used as a white fine particle, a lead carbonate basic (2PbCO₃.Pb(OH)₂) which is referred to as a white lead, ZnO referred to as a zinc white, a calcium carbonate (CaCO₃), a calcium sulfate hydrate (CaSO₄.2H₂O), and the like may be used.

As described above, with the semiconductor light emitting device according to the present embodiment, the ceramic fine particle 15 is made of the white fine particle, so that the light from the semiconductor light emitting element 14 (LED) is scattered by the white fine particles to be uniformly emitted in the phosphor layer. Accordingly, the semiconductor light emitting device without unevenness in the light can be provided. In addition, in the present embodiment, heat generated in the phosphor layer can be radiated, as in Embodiments 1 to 5. Therefore, a semiconductor light emitting device which achieves both uniform light-emission and high heat radiation can be provided. It should be noted that the effect achieved in each of Embodiments can be also achieved in the present embodiment.

### Embodiment 7

Next, a semiconductor light emitting device according to Embodiment 7 is described.

In the present embodiment, a diamond fine particle is used as a ceramic fine particle 15 used in the semiconductor light emitting device according to each of Embodiments 1 to 6. A diamond is transparent with respect to a visible light ray, and has an extremely high thermal conductivity. Therefore, only a small amount of diamond fine particles is dispersed in a silicone resin to substantially increase a thermal conductivity of a resin layer 17, to thereby improve heat radiation of the phosphor layer (quantum dot phosphor layer, and the like).

In the present embodiment, the diamond fine particle was formed using a vapor phase growth method. For the occasion, a thermal conductivity of the diamond fine particles alone was about 1200 W/mk. The thermal conductivity of about 15 W/mk was obtained which is the same level of the thermal conductivity of the silicone resin in which AlN fine particles are contained only at 10 vol %, by only containing the diamond fine particles only at 0.1 vol % in a volume ratio into the silicone resin. This is at the level of a hundred times of the thermal conductivity of the silicone resin which does not include the ceramic fine particles.

As described above, with the semiconductor light emitting device according to the present embodiment, the diamond fine particles are used to allow heat in a phosphor layer to be radiated at high efficiency. Accordingly, increase in the temperature of a quantum dot phosphor is effectively suppressed, to thereby provide the semiconductor light emitting device with high efficiency, high reliability, and high color rendering properties. It should be noted that the effect achieved in each of Embodiments can also be achieved in the present embodiment.

### Embodiment 8

Next, a semiconductor light emitting device according to Embodiment 8 is described.

A ceramic fine particle 15 may be a rare earth phosphor which absorbs light emitted from a semiconductor light emitting element 14 (LED) and emits excitation light of a quantum dot phosphor as fluorescence.

Accordingly, in Embodiment 8, a silicon aluminum nitride (SiAlON: Eu) phosphor to which an europium ion serving as the rare earth phosphor is added is used as a ceramic fine particle 15 in the semiconductor light emitting device according to each of Embodiment 1 to 6. Furthermore, a red quantum dot phosphor which provides red fluorescence was contained in a phosphor layer (quantum dot phosphor layer 19 and the like).

With this configuration, when the semiconductor light emitting element 14 is an LED which emits blue light, a part of the blue light emitted from the semiconductor light emitting element 14 is absorbed by SiAlON (Eu phosphor), to provide green fluorescence. In addition, a red quantum dot phosphor absorbs a part of green luminescence in the green fluorescence, to provide red fluorescence. With this, the semiconductor light emitting device with high color rendering properties can be achieved.

Furthermore, with this configuration, the quantum dot phosphor changes a wavelength from green to red. When the wavelength is changed from green to red, Stokes loss is smaller than the case when the wavelength is changed from blue to red, to thereby reduce heat generated in the quantum dot phosphor. Accordingly, increase in the temperature of a quantum dot phosphor can be further suppressed, to thereby provide the semiconductor light emitting device with high reliability.

As described above, with the semiconductor light emitting device according to the present embodiment, light from the semiconductor light emitting element undergoes wavelength conversion by ceramic fine particles, to thereby provide the semiconductor light emitting device with high color rendering properties and high reliability. It should be noted that the effect achieved in each of Embodiments can be also achieved in the present embodiment.

Although the semiconductor light emitting device according to the present disclosure is described in the above, the present disclosure is not limited to the aforementioned embodiments.

For example, the ceramic fine particle 15 may be a transparent fine particle which allows a visible light ray to pass through. With this, the light from the semiconductor light emitting element 14 is emitted to the phosphor layer without loss, to thereby provide the semiconductor light emitting device with high efficiency.

Those skilled in the art will readily appreciate that many modifications are possible in the exemplary embodiments without materially departing from the scope of the present disclosure, and such modifications are also included in the present disclosure. The structural elements in the embodiments may be arbitrarily combined without materially departing from the scope of the present disclosure.

### INDUSTRIAL APPLICABILITY

According to the present disclosure, a semiconductor light emitting device with high reliability, high efficiency, and high color rendering properties can be achieved, so that the semiconductor light emitting device is useful widely in a white LED light source and the like, such as a display device and a lighting device.

1. A semiconductor light emitting device comprising:
a package which is made of a resin and includes a recess;
a lead frame exposed to a bottom of the recess;
a semiconductor light emitting element connected to the lead frame in the recess;
a first resin layer in contact with the lead frame in the recess and over the bottom of the recess; and
a second resin layer above the first resin layer and the semiconductor light emitting element,
wherein the first resin layer includes a ceramic fine particle, and
the second resin layer includes at least one of semiconductor fine particles having an excitation fluorescence spectrum which differs according to a particle size, and a resin holding the semiconductor fine particles dispersedly.

2. The semiconductor light emitting device according to claim 1,
wherein the second resin layer is enclosed in a transparent substrate, and
the transparent substrate and the package surround an area which is filled with the first resin layer.

3. The semiconductor light emitting device according to claim 1, comprising
a third resin layer between the first resin layer and the semiconductor light emitting element, the third resin layer not including the ceramic fine particle.

4. The semiconductor light emitting device according to claim 2, comprising
a third resin layer between the first resin layer and the semiconductor light emitting element, the third resin layer not including the ceramic fine particle.

5. The semiconductor light emitting device according to claim 1,
wherein the second resin layer is formed by an electrodeposition method on a surface of a transparent substrate having an electrically conductive area, and is placed above the package to face the semiconductor light emitting element, and
the package has an inside which is filled with the first resin layer.

6. A semiconductor light emitting device comprising:
a package having a recess;
a semiconductor light emitting element mounted in the package; and
a resin layer which is formed inside the package, and holds, in a dispersed state, a phosphor which converts a wavelength and a ceramic fine particle,
wherein the phosphor includes an aggregation containing at least one quantum dot phosphor,
the aggregation is coated with a transparent acrylic resin film or a silicon oxide, and
the semiconductor light emitting element is coated with the resin layer.

7. The semiconductor light emitting device according to claim 1,
wherein the ceramic fine particle is a white fine particle which reflects a visible light ray.

8. The semiconductor light emitting device according to claim 1,
wherein the ceramic fine particle is a transparent fine particle which allows a visible light ray to pass through.

9. The semiconductor light emitting device according to claim 1,
wherein the ceramic fine particle is a diamond fine particle.

10. The semiconductor light emitting device according to claim 1,
wherein the ceramic fine particle absorbs light emitted from the semiconductor light emitting element, and emits excited light of the semiconductor fine particle as fluorescence.

11. The semiconductor light emitting device according to claim 1,
wherein the ceramic fine particle has the particle size in a range from 100 nm to 700 nm inclusive.
